(19) United States
(12) Patent Application Publication
(10) Pub. No.: US 2026/0165045 A1
(43) Pub. Date: Jun. 11, 2026

(54) SELECTIVE DEPOSITION OF SILICON NITRIDE

(71) Applicant: Applied Materials, Inc., Santa Clara, CA (US)

(72) Inventors: Aniruddh Shekhawat, Tempe, AZ (US); Ligang Gao, Chandler, AZ (US); Karthik Colinjivadi, Dublin, CA (US); Vahid Ghodsi Karbasdehi, Chandler, AZ (US)

(73) Assignee: Applied Materials, Inc., Santa Clara, CA (US)

(21) Appl. No.: 18/971,073

(22) Filed: Dec. 6, 2024

(51) Int. Cl. H01L 21/02; C23C 16/02; C23C 16/04; C23C 16/34

(52) U.S. Cl. CPC H10P 14/6514; C23C 16/02; C23C 16/04; C23C 16/345; H10P 14/69433

(57) ABSTRACT

Methods of forming devices by selective deposition of silicon nitride (SIN) layer on a titanium nitride (TiN) layer and not on a high-κ dielectric layer on the same substrate. The method including a pre-treatment process before selective deposition of the silicon nitride layer. The pre-treatment process comprising, in order, a first pre-treatment process to remove native oxides from the titanium nitride and passivate dangling bonds on the high-κ dielectric layer, and a second pre-treatment process to fluorinate the high-κ dielectric layer. After deposition, the fluorine can be removed from the high-κ dielectric layer. The selective deposition method occurring without formation of an inhibitor layer on the high-κ dielectric layer.

### TECHNICAL FIELD

Embodiments of the disclosure generally relate to methods of forming interconnect structures in microelectronic devices. More particularly, embodiments of the disclosure are directed to methods of improving selective deposition of silicon nitride on titanium nitride relative to a high-κ dielectric surface without use of a blocking layer.

### BACKGROUND

The semiconductor industry faces many challenges in the pursuit of device miniaturization including the rapid scaling of nanoscale features. Such challenges include the fabrication of complex devices, often using multiple lithography steps and etch processes. Furthermore, the semiconductor industry needs low cost alternatives to high cost EUV for patterning complex architectures. To maintain the progress of device miniaturization and keep chip manufacturing costs down, selective deposition has shown promise. It has the potential to remove costly lithographic steps by simplifying integration schemes.

Selective deposition of materials can be accomplished in a variety of ways. For instance, some processes may have inherent selectivity to surfaces based on their surface chemistry. These processes are rare, and typically specific to the reactants used, materials formed, and the substrate surfaces.

In addition, as the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications. Selective deposition methods typically include depositing a mask material on a substrate and patterning the mask material to form a patterned mask. Regions of the substrate may then be exposed though the patterned mask after the patterning of the mask. The patterned mask may be removed from the substrate to expose non-implanted regions of the substrate and a material may be selectively deposited on selected regions of the substrate. However, these methods utilizing a mask material, patterning the mask material and removing the mask require multiple process steps in several process flows.

Currently, selective deposition of a material onto a nitride layer versus a high-κ dielectric layer typically uses a self-assembled monolayer (SAM) to inhibit growth on the high-κ dielectric layer. After deposition, the SAM is either removed by a selective removal process, or remains in the final device affecting the continuity of conductivity between materials.

Accordingly, there is a need for methods for selectively depositing a material onto a nitride layer versus a high-κ dielectric layer without using a SAM growth inhibitor.

### SUMMARY

Embodiments of the disclosure are directed to methods of selectively depositing a film, the method includes exposing a substrate having a first area with a titanium nitride (TiN) layer and a second area with a high-κ dielectric layer to a pre-treatment process. The pre-treatment process includes, in order, a first pre-treatment process to remove native oxides from the titanium nitride (TiN) and passivate dangling bonds on the high-κ dielectric layer, and a second pre-treatment process to fluorinate the high-κ dielectric layer. A silicon nitride (SiN) layer is selectively deposited on the titanium nitride layer and not on the high-κ dielectric layer.

Additional embodiments of the disclosure are directed to methods of selectively depositing a film. The methods include exposing a substrate having a first area with a titanium nitride (TiN) layer and a second area with a hafnium oxide (HfO₂) layer to a pre-treatment process. The pre-treatment process includes, in order, a first pre-treatment process including hydrogen (H₂) plasma to remove native oxides from the titanium nitride layer and passivate dangling bonds on the hafnium oxide layer, and a second pre-treatment process including a fluorine-containing plasma with a mixture of NF₃ and NH₃ to fluorinate the hafnium oxide layer. A silicon nitride (SiN) layer is selectively deposited on the titanium nitride layer and not on the high-κ dielectric layer. The fluorine can then be removed from the hafnium oxide layer using a hydrogen (H₂) plasma.

Further embodiments of the disclosure are directed to methods of selectively depositing a film. The methods include exposing a substrate having a first area with a titanium nitride (TiN) layer and a second area with a hafnium oxide (HfO₂) layer to a pre-treatment process. The-treatment process consists essentially of, in order, a first pre-treatment process including a hydrogen (H₂) inductively coupled plasma to remove native oxides from the titanium nitride layer and passivate dangling bonds on the hafnium oxide layer, and a second pre-treatment process including a fluorine-containing plasma with a mixture of NF₃ and NH₃ at room temperature, and increasing temperature to greater than or equal to 80° C. to fluorinate the hafnium oxide layer. A silicon nitride (SiN) layer is selectively deposited on the titanium nitride layer and not on the high-κ dielectric layer. Then fluorine can be removed from the hafnium oxide layer using a hydrogen (H₂) plasma, wherein selective deposition occurs without formation of an inhibitor layer on the high-κ dielectric layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a portion of a microelectronic device during a stage of manufacture with one or more embodiments of the disclosure having a titanium nitride layer and a high-κ dielectric layer;

FIG. 1B illustrates a first pre-cleaning process resulting in removal of the impurities from the titanium nitride layer and passivation of dangling bonds from the surface of the high-κ dielectric layer shown in FIG. 1A;

FIG. 1C illustrates a second pre-cleaning process resulting in formation of surface modifications of the high-κ dielectric layer shown in FIG. 1B;

FIG. 1D illustrates the electronic device of FIG. 1C after formation of a silicon nitride layer selectively on the titanium nitride layer and no deposition on the high-κ dielectric layer;

FIG. 1E illustrates removal of the surface modifications from the high-κ dielectric layer; and

FIG. 2 illustrates a process flow diagram of a method of manufacturing a microelectronic device in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used herein, a “patterned substrate” refers to a substrate with a plurality of different material surfaces. In some embodiments, a patterned substrate comprises a first surface and a second surface. In some embodiments, the first surface comprises an oxide and the second surface comprises a metal, a metal nitride and/or a metal silicide.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

As used in this specification and the appended claims, the term “selectively depositing on a first surface over a second surface”, and the like, means that a first amount of a film or layer is deposited on the first surface and a second amount of film or layer is deposited on the second surface, where the second amount of film is less than the first amount of film, or no film is deposited on the second surface. The term “over” used in this regard does not imply a physical orientation of one surface on top of another surface but rather a relationship of the thermodynamic or kinetic properties of the chemical reaction with one surface relative to the other surface. For example, selectively depositing a molybdenum film onto a metal surface over an oxide surface means that the molybdenum film deposits on the metal surface and less or no molybdenum film deposits on the oxide surface; or that the formation of the molybdenum film on the metal surface is thermodynamically or kinetically favorable relative to the formation of a molybdenum film on the oxide surface.

In some embodiments, “selectively” means that the subject material forms on the target surface at a rate greater than or equal to about 10x, 15x, 20x, 25x, 30x, 35x, 40x, 45x or 50x the rate of formation on the non-selected surface. Stated differently, the selectivity for the target material surface relative to the non-selected surface is greater than or equal to about 10:1, 15:1, 20:1, 25:1, 30:1, 35:1, 40:1, 45:1 or 50:1.

Interconnects comprise metal lines that transfer current within the same device layer, and metal vias that transfer current between layers. These lines and vias are formed with conductive metal such as copper or cobalt in gaps formed within the device. In one or more embodiments, a dielectric layer comprises at least one feature defining a gap including sidewalls and a bottom. In one or more embodiments, the gap comprises the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate.

Currently, there is no state-of-the-art technology for depositing silicon nitride (SiN) on a nitride layer selectively over a high-κ dielectric layer without using a self-assembled monolayer (SAM) as a growth inhibitor on the high-κ dielectric layer. For example, there are no known techniques to selectively deposit silicon nitride (SiN) on titanium nitride (TiN) selectively over hafnium oxide (HfO₂). Some embodiments of the disclosure advantageously provide methods that enable the inhibition of silicon nitride film deposition on a hafnium oxide surface using a SAM-free approach using plasma pre-treatment of the hafnium oxide surface. Some embodiments of the disclosure advantageously provide a two-step plasma treatment process to modify the surface of the hafnium oxide material to inhibit silicon nitride growth thereon. A post-deposition surface treatment removes residual fluorine from the hafnium oxide material to maintain device quality.

Accordingly, one or more embodiments of the disclosure are directed to methods for selectively depositing a film, or forming a microelectronic device. In some embodiments, the method forms a silicon nitride (SiN) layer on a titanium nitride (TiN) layer selectively over a high-κ dielectric layer. In particular embodiments, the method of forming a film for a microelectronic device comprises formation of a silicon nitride (SiN) layer on a titanium nitride (TiN) layer selectively over a hafnium oxide (HfO₂) layer.

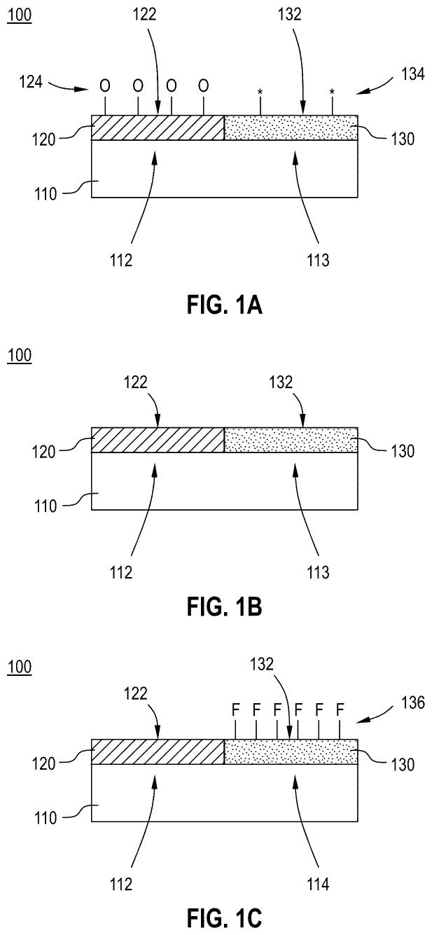

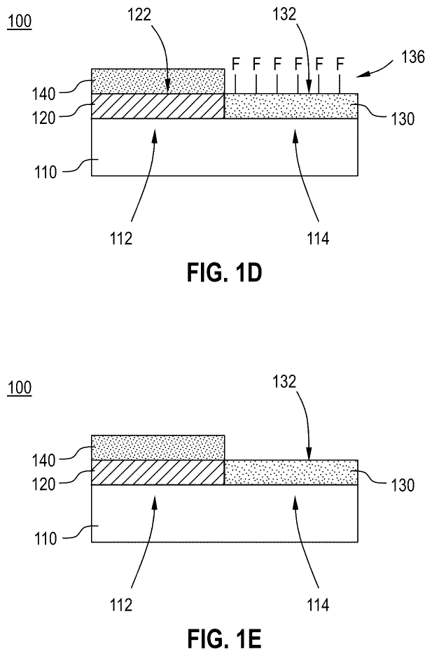

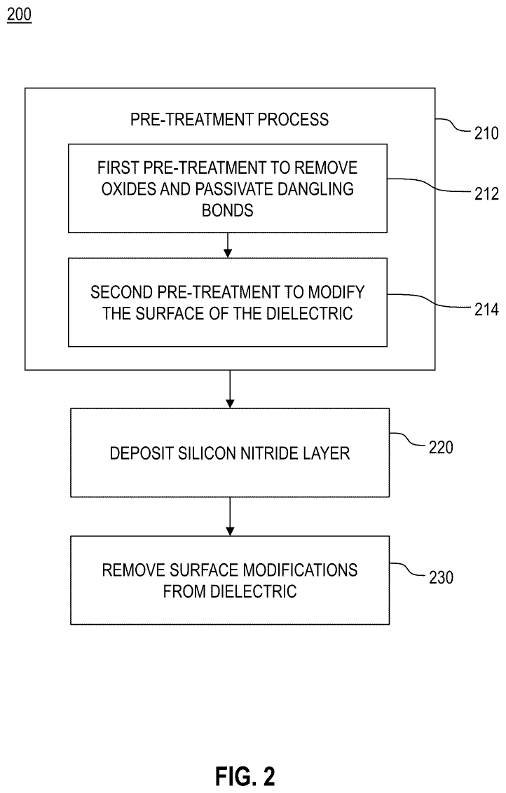

Methods of forming microelectronic devices 100 are described herein with reference to FIGS. 1A through 1E. FIG. 2 is a flow chart of an exemplary method 200 of forming microelectronic devices with respect to FIGS. 1A through 1E.

FIG. 1A illustrates a microelectronic device 100 in the process of being formed according to method 200. The substrate 110 of the microelectronic device 100 has a first area 112 with a first layer and a second area 113 with a second layer that is different than the first layer. In some embodiments, the first area 112 has a titanium nitride (TiN) layer 120 with a titanium nitride layer surface 122, and the second area 113 has a high-κ dielectric layer 130 with a high-κ dielectric surface 132.

The titanium nitride surface 122 illustrated has oxygen terminations, also referred to as an oxide layer. The oxide layer can be an intentionally formed oxide layer (i.e., from a process intended to produce the oxide layer) or a native oxide layer (i.e., from natural exposure to atmospheric conditions which allow for the formation of some surface oxides. In the embodiment shown in the Figures, the titanium nitride surface 122 comprises a native oxide layer 124.

The high-κ dielectric surface 132 illustrated has surface radicals, also referred to as dangling bonds 134. Dangling bonds, also referred to as immobilized free radicals, act chemically similar to a free radical, resulting in a highly reactive surface moiety.

The high-κ dielectric layer 130 can include any suitable high-κ dielectric known to the skilled artisan. In some embodiments, the high-κ dielectric layer 130 comprises one or more of hafnium oxide (HfO₂), zirconium oxide (ZrO₂), lanthanum oxide (La₂O₃), scandium oxide (Sc₂O₃), yttrium oxide (Y₂O₃), lutetium oxide (Lu₂O₃), niobium oxide (Nb₂O₅), or tantalum oxide (Ta₂O₅).

The method 200 is a selective deposition process that occurs without the formation of an inhibitor layer. As used in this specification and the appended claims, an inhibitor layer is a discrete layer that is formed on the surface of a material. For example, inhibitor layers frequently include self-assembled monolayers (SAMs) that have a head group that forms a chemical bond with the surface of the subject layer, and a tail group that extends from the head group. SAM head groups are often hydrophilic and the tail group is hydrophobic so that the SAM head groups pack together on the surface and the tail groups extend from the surface. A self-assembled monolayer is an example of an inhibitor, and embodiments of the disclosure selectively deposit a film without the use of an inhibitor.

A surface modification is different from an inhibitor layer. Material surfaces have natural terminations which can be modified to allow for selective deposition. For example, a high-κ dielectric material may have dangling bonds, also referred to as immobilized free radicals, which act chemically similar to a free radical. A surface with dangling bonds can be modified in a manner to remove the dangling bonds by satisfying the valence of the affected surface atoms. Another example of a surface modification that is not an inhibitor is the replacement of a hydroxide terminated surface with a fluoride terminated surface. While the surface chemistry is changed, there is no discrete inhibitor layer.

At operation 210 of method 200, the substrate 110, with the titanium nitride layer 120 and the high-κ dielectric layer 130 is subjected to a pre-treatment process. The pre-treatment process of operation 210 comprises, in order, a first pre-treatment process 212 and a second pre-treatment process 214.

The first pre-treatment process 212 exposes the titanium nitride layer 120 and the high-κ dielectric layer 130 to conditions that remove oxides from the titanium nitride layer 120 and surface radicals from the high-κ dielectric layer 130, as illustrated in FIG. 1B. In some embodiments, the first pre-treatment process 212 results in the removal of the native oxide layer 124 from the titanium nitride surface 122 of the titanium nitride layer 120. In some embodiments, the first pre-treatment process 212 results in the passivation of the dangling bonds 134 on the high-κ dielectric surface 132 of the high-κ dielectric layer 130. As used in this manner, passivation of the dangling bonds means that the surface free radicals are removed by satisfying the valence of the surface atoms. In some embodiments, the first pre-treatment process 212 results in both removal of the native oxide layer 124 from the titanium nitride layer 120 and the passivation of the dangling bonds 134 from the high-κ dielectric layer 130.

In some embodiments, the first pre-treatment process 212 comprises exposing the substrate 110, with the titanium nitride layer 120 and the high-κ dielectric layer 130 to a hydrogen (H₂) plasma. As used in this specification and the appended claims, the term hydrogen plasma, and the like, refers to a plasma comprising or consisting essentially of molecular hydrogen (H₂). A hydrogen-containing plasma can include other compounds in addition to molecular hydrogen and/or compounds that have reactive hydrogen atoms. In some embodiments, the hydrogen plasma is an inductively coupled plasma (ICP).

The first pre-treatment process 212 can be performed at any suitable temperature and pressure. In some embodiments, the first pre-treatment process 212 is performed at a temperature less than or equal to 500° C., 450° C., 400° C., 350 or 300° C. In some embodiments, the first pre-treatment process 212 has a plasma frequency greater than or equal to 13.56 MHz, 20 MHz, 40 MHz, 60 MHz or 100 Mhz. In some embodiments, the frequency of the first pre-treatment process 212 is greater than a frequency used in the second pre-treatment process 214 as described further below. In some embodiments, the first pre-treatment process 212 has a plasma with a power in the range of 500 W to 2 kW.

After removal of the oxide layer (e.g., native oxide layer 124) from the titanium nitride layer 120 and/or passivation of the dangling bonds 134 of the high-κ dielectric layer 130, a second pre-treatment process 214 is performed as part of operation 210 of method 200. The second pre-treatment process 214 of some embodiments results in the surface modification of the high-κ dielectric layer 130 to decrease subsequent deposition on the high-κ dielectric layer 130. In some embodiments, the second pre-treatment process results in fluorination of the high-κ dielectric layer 130 to result in fluorine terminations 136 on the high-κ dielectric layer 130, as illustrated in FIG. 1C.

In some embodiments, the second pre-treatment process 214 comprises exposing the substrate 110 with the titanium nitride layer 120 and the high-κ dielectric layer 130 to a fluorine-containing plasma. As used herein, a “fluorine-containing plasma” can include molecular fluorine (F₂) and/or compounds with reactive fluorine atoms, for example, carbon tetrafluoride (CF₄), nitrogen trifluoride (NF₃), trifluoromethane (CHF₃), difluoromethane (CH₂F₂), hexafluoro-1,3-butadiene (C₄F₆), octafluorocyclobutane (C₄F₈)], etc. In some embodiments, the fluorine-containing plasma comprises or consists essentially of nitrogen trifluoride (NF₃). As used in this manner, the term “consists essentially of” means that the composition of the reactive species in the plasma is greater than or equal to 95%, 98%, or 99% of the stated species. In some embodiments, the fluorine-containing plasma comprises a mixture of nitrogen trifluoride (NF₃) and ammonia (NH₃). In some embodiments, the fluorine-containing plasma comprises a mixture of nitrogen trifluoride (NF₃) and ammonia (NH₃) in a flow ratio in the range of 1:10-1:30, or in the range of 1:15-1:25, or 1:20.

In some embodiments, the fluorine-containing plasma used in the second pre-treatment process 214 is an inductively coupled plasma (ICP).

In some embodiments, the second pre-treatment process 214 comprises exposing the substrate 110 with titanium nitride layer 120 and the high-κ dielectric layer 130 to a fluorine-containing plasma at room temperature (20° C. to 30° C., or 25° C.) for a first period of time, and increasing temperature to greater than or equal to 80° C. for a second period of time to sublimate reaction products. In some embodiments, the second pre-treatment process 214 has a plasma frequency less than or equal to 2 MHz, or 900 Hz. In some embodiments, the second pre-treatment process 214 has a plasma power in the range of 500 W to 2 kW.

In some embodiments, the pre-treatment process of operation 210 includes more than the first pre-treatment process 212 and the second pre-treatment process 214. In some embodiments, the pre-treatment process of operation 210 consists essentially of the first pre-treatment process 212 followed by the second pre-treatment process 214. As used in this manner, “consists essentially of” means that there are not additional chemically reactive processes included in the pre-treatment process.

After the pre-treatment process at operation 210, a silicon nitride layer 140 is selectively formed at operation 220, as shown in FIG. 1D. The silicon nitride layer 140 is deposited on the titanium nitride layer 120 and not on the high-κ dielectric layer 130. Stated differently, in some embodiments, operation 220 forms substantially no silicon nitride on the high-κ dielectric layer 130. As used in this manner, the term “substantially no silicon nitride” means that less than 5%, 2% or 1% of the surface area of the high-κ dielectric layer 130 has silicon nitride formed thereon.

Selective deposition of the silicon nitride layer 140 can be performed by any suitable technique known to the skilled artisan. In some embodiments, depositing the silicon nitride layer 140 comprises an atomic layer deposition (ALD) process or a chemical vapor deposition (CVD) process.

In a typical ALD process, alternating pulses or flows of “A” precursor and “B” precursor can be used to deposit a film. The alternating exposure of the surface to reactants “A” and “B” is continued until the desired thickness film is reached. However, instead of pulsing the reactants, the gases can flow simultaneously from one or more gas delivery head or nozzle and the substrate and/or gas delivery head can be moved such that the substrate is sequentially exposed to each of the reactive gases. Of course, the aforementioned ALD cycles are merely exemplary of a wide variety of ALD process cycles in which a deposited layer is formed by alternating layers of precursors and co-reactants.

In one or more embodiments, reactants and/or co-reactants are in vapor or gas form. The reactants may be delivered with a carrier gas. A carrier gas, a purge gas, a deposition gas, or other process gas may contain nitrogen, hydrogen, argon, neon, helium, or combinations thereof. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

After formation of the silicon nitride layer 140 at operation 220 of method 200, the surface modifications of the high-κ dielectric layer 130 are optionally removed at operation 230. In some embodiments, the high-κ dielectric layer 130 is modified with fluorine terminations and operation 230 removes the fluorine terminations, as shown in FIG. 1E.

In some embodiments, removing the surface modifications at operation 230 comprises exposure to a plasma. In some embodiments, the plasma is one or more of a hydrogen (H₂) plasma, a helium (He) plasma or an argon (Ar) plasma. The plasma can be any suitable plasma including, but not limited to, an inductively coupled plasma (ICP). In one or more embodiments, the plasma treatment process used to remove the surface modifications at operation 230 also increases the density of the deposited silicon nitride layer 140.

In some embodiments, the pressure of the processing chamber is controlled. The pressure of the processing chamber may be any suitable pressure for forming the blocking layer. In some embodiments, the pressure of the processing chamber is maintained at less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr. In some embodiments, the pressure of the processing chamber is maintained at about 10 Torr, about 20 Torr, about 30 Torr, about 40 Torr, or about 50 Torr.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film. In some embodiments, the optional post-processing operation comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes.

In some embodiments, the pre-cleaning process of operation 210 occurs in a single processing chamber. For example, both first pre-cleaning process 212 and second pre-cleaning process 214 are performed in a single process chamber. In some embodiments, the substrate is moved from a first chamber to a separate chamber for the first pre-cleaning process 212 and the second pre-cleaning process 214. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Any suitable cluster tools may be adapted for the present disclosure. However, the exact arrangement and combination of chambers may be altered for the purposes of performing specific steps of a process as described herein. Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of selectively depositing a film, the method comprising:
exposing a substrate having a first area with a titanium nitride (TiN) layer and a second area with a high-κ dielectric layer to a pre-treatment process, the pre-treatment process comprising, in order,
a first pre-treatment process to remove native oxides from the titanium nitride (TiN) and passivate dangling bonds on the high-κ dielectric layer, and
a second pre-treatment process to fluorinate the high-κ dielectric layer and form a fluorinated high-κ dielectric layer; and
selectively depositing a silicon nitride (SiN) layer on the titanium nitride layer and not on the high-κ dielectric layer.

2. The method of claim 1, wherein the high-κ dielectric comprises one or more of hafnium oxide (HfO₂), zirconium oxide (ZrO₂), lanthanum oxide (La₂O₃), scandium oxide (Sc₂O₃), yttrium oxide (Y₂O₃), lutetium oxide (Lu₂O₃), niobium oxide (Nb₂O₅), or tantalum oxide (Ta₂O₅).

3. The method of claim 2, wherein the high-κ dielectric layer consists essentially of hafnium oxide (HfO₂).

4. The method of claim 1, wherein the first pre-treatment comprises a hydrogen plasma.

5. The method of claim 4, wherein the hydrogen plasma is an inductively coupled plasma (ICP).

6. The method of claim 1, wherein the second pre-treatment comprises a fluorine-containing plasma.

7. The method of claim 6, wherein the fluorine-containing plasma is an inductively coupled plasma (ICP).

8. The method of claim 6, wherein the fluorine-containing plasma comprises a mixture of NF₃ and NH₃.

9. The method of claim 8, the second pre-treatment comprises exposing the substrate to a fluorine-containing plasma at room temperature, and increasing temperature to greater than or equal to 80° C. to sublimate reaction products.

10. The method of claim 1, further comprising removing fluorine from the fluorinated high-κ dielectric layer.

11. The method of claim 10, wherein removing the fluorine comprises exposing the substrate to a hydrogen (H₂) plasma.

12. The method of claim 1, wherein selective deposition occurs without formation of an inhibitor layer on the high-κ dielectric layer.

13. The method of claim 1, wherein selectively depositing the silicon nitride layer comprises an atomic layer deposition (ALD) process or a chemical vapor deposition (CVD) process.

14. A method of selectively depositing a film, the method comprising:
exposing a substrate having a first area with a titanium nitride (TiN) layer and a second area with a hafnium oxide (HfO₂) layer to a pre-treatment process, the pre-treatment process comprising, in order,
a first pre-treatment process comprising hydrogen (H₂) plasma to remove native oxides from the titanium nitride layer and passivate dangling bonds on the hafnium oxide layer, and
a second pre-treatment process comprising a fluorine-containing plasma with a mixture of NF₃ and NH₃ to fluorinate the hafnium oxide layer;
selectively depositing a silicon nitride (SiN) layer on the titanium nitride layer and not on the hafnium oxide layer; and
removing fluorine from the hafnium oxide layer using a hydrogen (H₂) plasma.

15. The method of claim 14, wherein the hydrogen plasma is an inductively coupled plasma (ICP).

16. The method of claim 14, wherein the fluorine-containing plasma is an inductively coupled plasma (ICP).

17. The method of claim 14, the second pre-treatment comprises exposing the substrate to a fluorine-containing plasma at room temperature, and increasing temperature to greater than or equal to 80° C. to sublimate reaction products.

18. The method of claim 17, wherein the fluorine-containing plasma comprises nitrogen trifluoride (NF₃) and ammonia (NH₃) in a flow ratio of 1:20.

19. The method of claim 14, wherein selective deposition occurs without formation of an inhibitor layer on the hafnium oxide layer.

20. A method of selectively depositing a film, the method comprising:
exposing a substrate having a first area with a titanium nitride (TiN) layer and a second area with a hafnium oxide (HfO₂) layer to a pre-treatment process, the pre-treatment process consisting essentially of, in order,
a first pre-treatment process comprising a hydrogen (H₂) inductively coupled plasma to remove native oxides from the titanium nitride layer and passivate dangling bonds on the hafnium oxide layer, and
a second pre-treatment process comprising a fluorine-containing plasma with a mixture of NF₃ and NH₃ at room temperature, and increasing temperature to greater than or equal to 80° C. to fluorinate the hafnium oxide layer;
selectively depositing a silicon nitride (SiN) layer on the titanium nitride layer and not on the hafnium oxide layer; and
removing fluorine from the hafnium oxide layer using a hydrogen (H₂) plasma,
wherein selective deposition occurs without formation of an inhibitor layer on the hafnium oxide layer.
